(19) United States
(12) Patent Application Publication
(10) Pub. No.: US 2026/0190245 A1
(43) Pub. Date: Jul. 2, 2026

(54) METHODS FOR FORMING SEED LAYER AND PLASMA ETCHING PROCESS

(71) Applicant: Absolics Inc., Covington, GA (US)

(72) Inventors: SeHan YUN, Covington, GA (US); Chun Jae LEE, Covington, GA (US); DAE HWAN KIM, Covington, GA (US)

(73) Assignee: Absolics Inc., Covington, GA (US)

(21) Appl. No.: 19/426,080

(22) Filed: Dec. 19, 2025

Related U.S. Application Data
(60) Provisional application No. 63/740,329, filed on Dec. 31, 2024.

(51) Int. Cl. H05K 3/16; H05K 3/00

(52) U.S. Cl. CPC H05K 3/16; H05K 3/0041; H05K 2203/0554

(57) ABSTRACT

According to embodiments, a method for forming a seed layer comprises: an operation of forming an ion-passage hole by removing a portion of an insulating layer in a workpiece arranged such that a metal-pattern layer is disposed below and the insulating layer is disposed over it; a masking operation of forming a metal mask layer on the insulating layer; and a sputtering operation of forming a seed layer on the insulating layer by plasma sputtering; wherein the metal mask layer is connected to the metal-pattern layer through a sidewall surface of the ion-passage hole.

### CROSS-REFERENCE TO RELATED APPLICATION

This application claims priority of U.S. Provisional Patent Application No. 63/740,329, filed on December 31, 2024, the entire disclosure of which is hereby incorporated by reference for all purposes.

### BACKGROUND

### Technical Field

Embodiments relate to a method for forming a seed layer and to a plasma etching method, by which occurrence of arcing is suppressed so that processes may be performed with high reliability.

### DESCRIPTION OF RELATED ART

There are numerous types of sputtering systems, which are used to deposit ductile or conductive coatings. Sputtering is applied in the wiring formation process of a packaging substrate.

“Sputtering” refers to a process of forming a thin film by causing ionized gas atoms to collide with a target material. In other words, sputtering is a process in which high-energy ions collide with the target at high speed and the ejected metal particles are deposited on a substrate, and it may be classified into DC sputtering, RF sputtering, and reactive ion sputtering.

DC sputtering is a deposition process in which DC (direct current) power is applied into a chamber equipped with a sputtering target to place an inert gas within the chamber into a plasma state. RF sputtering is a deposition process in which RF (radio frequency) voltage, i.e., AC (alternating current) power, is applied into a chamber equipped with a sputtering target to place an inert gas within the chamber into a plasma state.

During such an RF sputtering process, when RF power is applied into the chamber, an arc may occur; such arcing may cause damage to a substrate or may cause equipment failure. Therefore, it is necessary to minimize arcing within the chamber.

Related art includes Korean Patent No. 10-1324584 and Korean Patent No. 10-2634683.

### SUMMARY

In some embodiments, a method for forming a seed layer and a plasma etching method, by which occurrence of arcing is suppressed so that processes may be performed with high reliability are provided.

In some embodiments, a method for forming a seed layer and a plasma etching method that, in manufacturing a packaging substrate employing a glass core, suppress dielectric breakdown caused by electrons accumulated particularly in a hole-shaped via due to ion surface-charge crowding induced by plasma on a highly insulating substrate, thereby substantially suppressing phenomena such as substrate breakage or burning of an electrically conductive pattern are provided.

According to the embodiments, a method for forming a seed layer includes: an operation of forming a hole by removing a portion of an insulating layer on a workpiece arranged such that a metal-pattern layer is below and the insulating layer is above, thereby providing an ion-passage hole; a masking operation of forming a metal mask layer on the insulating layer; and a sputtering operation of forming a seed layer on the insulating layer by plasma sputtering; wherein the metal mask layer is connected to the metal-pattern layer through a sidewall surface of the ion-passage hole.

The ion-passage hole may be provided so that at least a portion of the metal-pattern layer is exposed.

The sidewall surface of the ion-passage hole may allow charge transfer between the metal mask layer and the metal-pattern layer.

A glass core may be disposed under the metal-pattern layer.

The insulating layer may be an upper insulating layer disposed over the glass core.

The metal-pattern layer may be a core electrically conductive layer or an upper electrically conductive layer.

The ion-passage hole may be formed by laser drilling the insulating layer.

The sputtering operation may include positioning the workpiece in a process chamber, evacuating the process chamber, generating plasma, and depositing a target material on a substrate.

Through the ion-passage hole, a potential difference between the metal mask layer and the metal-pattern layer may be suppressed.

In the sputtering operation, occurrence of dielectric breakdown may be substantially suppressed.

According to the embodiments, there is provided a plasma etching method including: an operation of forming a hole by removing a portion of an insulating layer on a workpiece arranged such that a metal-pattern layer is below and the insulating layer is above, thereby providing an ion-passage hole; a masking operation of disposing a metal mask layer on the insulating layer; and a via-forming operation of providing a blind via on the insulating layer by plasma etching; wherein the metal mask layer is connected to the metal-pattern layer through a sidewall surface of the ion-passage hole.

The ion-passage hole may be provided so that at least a portion of the metal-pattern layer is exposed.

The sidewall surface of the ion-passage hole may allow charge transfer between the metal mask layer and the metal-pattern layer.

### BRIEF DESCRIPTION OF THE DRAWINGS

FIG. 1 is a schematic cross-sectional process sequence illustrating formation of an electrically conductive layer and an insulating layer on a glass core.

FIG. 2 is a schematic cross-sectional process sequence explaining how arcing occurs when a plasma sputtering process is performed according to a conventional method.

FIG. 3 is a schematic cross-sectional process sequence illustrating, according to the embodiments, a state in which a stable ion distribution is obtained during a plasma sputtering process.

### DESCRIPTION OF THE EMBODIMENTS

Hereinafter, embodiments will be described in detail with reference to the accompanying drawings so that those skilled in the art may readily carry out the present invention. However, the present invention may be embodied in various different forms and is not limited to the embodiments set forth herein. Throughout the specification, like reference numerals denote like parts.

Throughout this specification, the term “combination thereof” included in a Markush-type expression means one or more mixtures or combinations selected from the group of components recited in the Markush-type expression, and means that one or more selected from the group of those components may be comprised.

In this specification, terms such as “first,” “second,” or “A,” “B” are used to distinguish identical terms from each other. Also, unless the context clearly indicates otherwise, singular forms include plural forms.

In this specification, the expression “~-based” may mean that a compound corresponding to “~” or a derivative of “~” is included within a compound.

In this specification, that “B is disposed over A” means that B may be disposed directly on A or with another layer interposed therebetween while B is disposed over A, and is not to be construed as being limited to B contacting the surface of A.

In this specification, that “B is connected to A” means that A and B may be directly connected or connected via another component interposed between A and B, and, unless otherwise stated, is not to be construed as being limited to direct connection between A and B.

In this specification, unless otherwise described, singular terms are to be construed, in light of the context, as encompassing both singular and plural.

In the drawings of this specification, the shapes, relative sizes, angles, and the like of respective components are exemplary and may be exaggerated for purposes of explanation, and the scope of rights is not to be construed as limited to the drawings.

In this specification, that “A and B are adjacent” means that A and B may be in contact with each other or may be located close to each other without being in contact. Unless otherwise stated, the expression that A and B are adjacent is not to be construed as being limited to A and B being in contact.

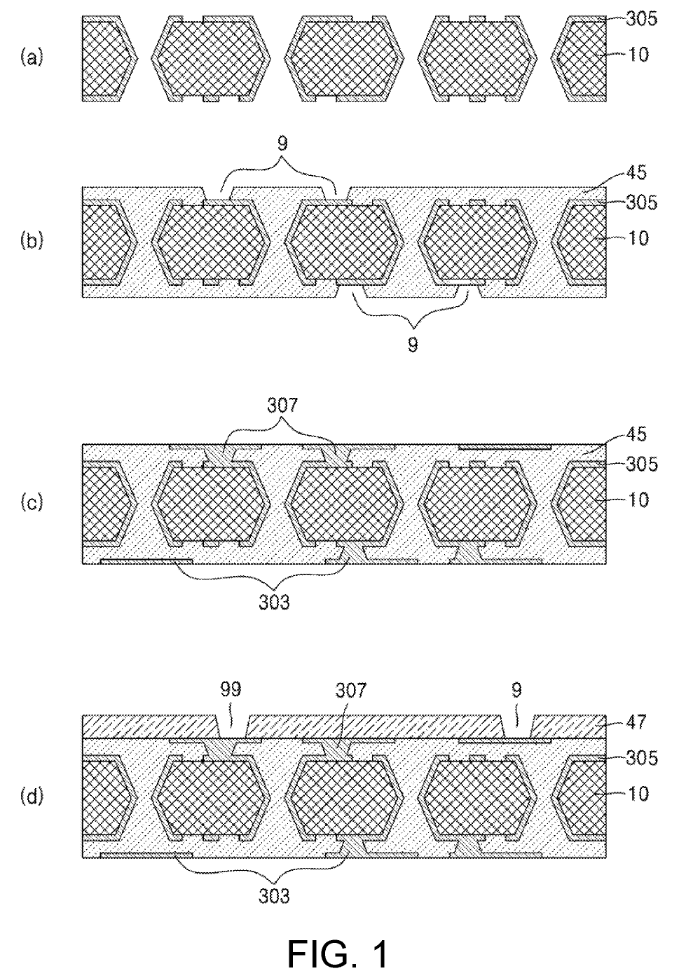

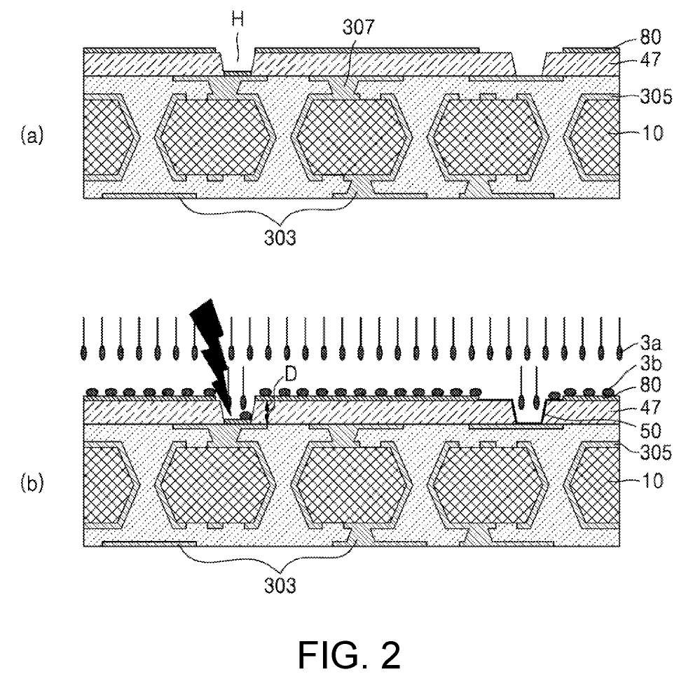

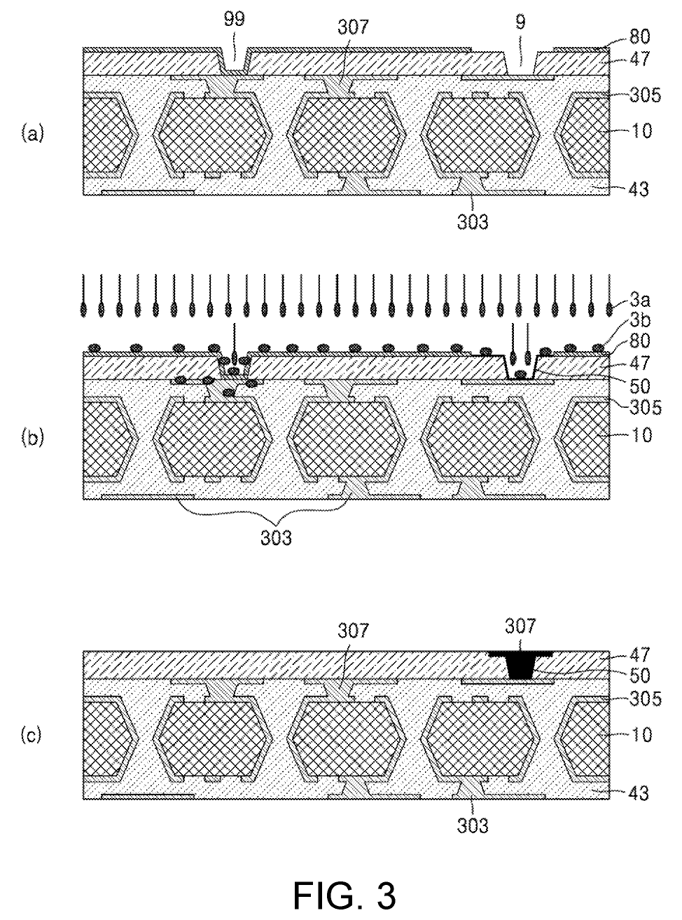

FIG. 1 is a schematic cross-sectional process sequence illustrating formation of an electrically conductive layer and an insulating layer on a glass core; FIG. 2 is a schematic cross-sectional process sequence explaining a progression of arcing that occurs when a plasma sputtering process is performed according to a conventional method; and FIG. 3 is a schematic cross-sectional process sequence illustrating, according to the embodiments, a state in which a stable ion distribution is obtained during a plasma sputtering process. With reference to FIGS. 1 to 3, embodiments will be described in greater detail below.

In order to achieve the above object, a seed-layer forming method according to one embodiment of the embodiments comprises: a hole-forming operation; a masking operation; and a sputtering operation.

The hole-forming operation is an operation of providing an ion-passage hole 99 by removing a portion of an insulating layer on a workpiece arranged such that a metal-pattern layer is below and the insulating layer is above.

The ion-passage hole 99 may be provided so that at least a portion of the metal-pattern layer is exposed.

The ion-passage hole 99 may, for example, be formed in the insulating layer by a method such as laser drilling (laser etch-drilling), but is not limited thereto.

The ion-passage hole 99 may, for example, have a diameter of 12 µm or more, 16 µm or more, 20 µm or more, 24 µm or more, or 28 µm or more. In addition, the diameter may be 100 µm or less, 80 µm or less, 60 µm or less, 50 µm or less, 45 µm or less, or 40 µm or less. If the diameter of the ion-passage hole 99 is too small, the hole-forming process may be difficult; if the diameter is too large, the process may be needlessly consumed.

The masking operation is an operation of disposing a metal mask layer on the insulating layer.

A conventional method for forming a metal mask layer may be applied to the metal mask layer.

(a) of FIG. 2 shows a state in which a metal mask layer 80 is disposed according to a conventional method. The metal mask layer is disposed over a portion to be masked and, for example, is disposed over an upper surface of the workpiece to be masked. When a hole (h) is provided in the workpiece and the hole (h) is located at a portion where masking is required, only the bottom surface of the hole is, in practice, provided with the metal mask layer 80.

(a) of FIG. 3 shows a state in which a metal mask layer 80 is disposed according to the embodiments. The metal mask layer is disposed over a portion to be masked and, for example, is disposed over an upper surface of the workpiece to be masked. When a hole (h) is provided in the workpiece and the hole (h) is located at a portion where masking is required, unlike the conventional art described above, the metal mask layer 80 is provided not only on the bottom surface of the hole but also on a side surface thereof.

Specifically, the metal mask layer 80 is connected to the metal-pattern layer through a sidewall surface of the ion-passage hole 99.

The sidewall surface of the ion-passage hole 99 may allow charge transfer between the metal mask layer 80 and the metal-pattern layer.

The sputtering operation is an operation of forming a seed layer 50 on the insulating layer by plasma sputtering.

A conventional method for forming a seed layer may be applied to the seed layer 50. For example, titanium, titanium nitride, copper, tantalum, cobalt, or nickel may be employed, but the embodiments are not limited thereto. In addition, plasma sputtering may be implemented by positioning the workpiece in a process chamber in which a metal target is disposed, evacuating the chamber, and performing sputtering, but is not limited thereto.

(b) of FIG. 2 illustrates a process of forming a plasma seed layer using a workpiece prepared according to a conventional method. In a plasma process, ions 3a collide with the surface of the workpiece substrate, and charge accumulates 3b on the surface of the workpiece substrate. In particular, when a metal mask layer is applied, accumulated charges build up on the metal mask layer, and when the accumulated charge exceeds a certain level, arcing occurs. When charges respectively accumulate in the metal mask layer on the insulating layer and in the metal mask layer or the electrically conductive layer under a blind via, despite the insulating layer present between them, the surface potential may momentarily crowd between them, making arcing likely. This is referred to as dielectric breakdown, and in specific phenomena, not only simple arcing but also physical damage to the substrate may occur, such as substrate cracking, electrode oxidation, or oxidation of the insulating layer.

(b) of FIG. 3 is an example prepared according to the embodiments. The sidewall surface of the ion-passage hole 99 allows charge 3a transfer between the metal mask layer 80 and the metal-pattern layer. Thus, even if charge accumulates 3b on the metal mask layer 80 during plasma sputtering, the charge is transferred to the metal-pattern layer through the sidewall surface, thereby reducing a charge-density difference between an upper portion and a lower portion of the ion-passage hole 99. Since the metal-pattern layer is often disposed also under a blind via, which is the target for seed-layer formation, the charge-density difference between an upper surface of the insulating layer and a bottom surface of the blind via across the blind via is reduced. Through this, occurrence of dielectric-breakdown phenomena may be substantially suppressed.

The sputtering operation is an operation of positioning the workpiece in a process chamber, evacuating the process chamber to vacuum conditions, generating plasma, and depositing a target material on a substrate.

Through the ion-passage hole 99, occurrence of a potential difference between the metal mask layer 80 and the metal-pattern layer may be suppressed.

In the sputtering operation, occurrence of dielectric-breakdown phenomena may be substantially suppressed.

Thereafter, an electrode or an electrically conductive layer may be formed by, e.g., copper plating (see (c) of FIG. 3), whereby an electrically conductive layer such as a via electrode may be formed with high reliability.

Application of the above method to a packaging substrate will be explained with reference to the drawings.

The glass core 10 is a material having high insulating properties, which reduces concern over parasitic elements and, as compared with a substrate such as silicon, has an advantage of enabling large-area production. Although the insulating property confers an advantage of more stable functioning particularly when a high frequency is applied, in the manufacturing process, due to the characteristics of high insulation and capability for large-area production, the substrate may be more readily exposed to dielectric-breakdown phenomena.

The glass core 10 has through electrodes, and a core electrically conductive layer 305 may be disposed on the surface in a predetermined pattern. An interfacial layer (not shown) for enhancing adhesion between the glass and the electrically conductive layer may be disposed therebetween; for example, a primer layer or a sputtered layer may be disposed, but the embodiments are not limited thereto (see (a) of FIG. 1).

An insulating layer is disposed on the glass core 10. An insulating layer formed inside the through electrode or on the surface of the glass core 10 is referred to as a core insulating layer 45 (see (b) of FIG. 1), and an organic insulating layer, an inorganic insulating layer, or an organic-inorganic composite insulating layer may be applied. For example, an Ajinomoto build-up layer may be applied, but the embodiments are not limited thereto.

An upper electrically conductive layer 307 may be disposed over the core insulating layer 45. The pattern may be formed by a lithography process, and the electrically conductive layer may be formed by a method such as copper plating. Before copper plating, it is preferable to form a seed layer; coating of an organic-inorganic composite primer layer including a copper seed, formation of a sputtered layer, and the like may be applied. Thereafter, copper plating is performed, and further processes such as surface etching may be carried out to provide one layer of the upper electrically conductive layer (see (c) of FIG. 1).

An insulating layer may be disposed between one layer of the upper electrically conductive layer, and a via or the like may be formed by etching a portion thereof (see (d) of FIG. 1). In (d) of FIG. 1, for convenience of explanation, the color of the upper insulating layer 47 is depicted differently; however, its boundary may not be identifiable in cross-section.

Subsequent processes will be explained with reference to FIG. 3.

Vias formed in the upper insulating layer 47 may comprise a mixture of the ion-passage hole 99 and the blind via 9. For example, after the ion-passage hole 99 is first formed by a method such as laser drilling, a metal mask layer 80 is applied as described below, and the blind via 9 may be formed by plasma etching.

Before plasma etching, the metal mask layer 80 is formed such that at least a portion of the metal mask layer 80 is disposed on a sidewall surface of the ion-passage layer. The metal mask layer 80 on the sidewall surface is connected to the electrically conductive layer on the lower side of the ion-passage layer, and may serve as an ion passage to alleviate excessive charge accumulation.

Thereafter, a seed layer 50 is provided in the blind via 9 through a plasma sputtering process, and a blind-via electrode serving as the upper electrically conductive layer 307 may be provided by a method such as electroplating.

Although the drawings and description omit description of the lower layer, a lower electrically conductive layer 303 or a lower insulating layer 43 may be disposed in the lower layer similarly to the upper layer.

According to another embodiment, a plasma etching method comprises: a hole-forming operation of providing an ion-passage hole by removing a portion of an insulating layer on a workpiece arranged such that a metal-pattern layer is below and the insulating layer is above; a masking operation of disposing a metal mask layer on the insulating layer; and a via-forming operation of providing a blind via on the insulating layer by plasma etching; wherein the metal mask layer is connected to the metal-pattern layer through a sidewall surface of the ion-passage hole.

The ion-passage hole is provided so that at least a portion of the metal-pattern layer is exposed, and the sidewall surface of the ion-passage hole may allow charge transfer between the metal mask layer and the metal-pattern layer.

The plasma etching method, similarly to the above plasma sputtering process, may provide a blind via without application of dielectric breakdown.

The seed-layer forming method and plasma etching method according to the embodiments may suppress arcing during plasma processing, thereby providing methods by which processes may be performed with high reliability.

In manufacturing a packaging substrate employing a glass core, the methods may substantially suppress occurrence of phenomena such as substrate breakage or burning of an electrically conductive pattern by suppressing dielectric breakdown caused by electrons accumulated particularly in a hole-shaped via due to ion surface-charge crowding induced by plasma on a highly insulating substrate.

While preferred embodiments of the present invention have been described in detail above, the scope of the present invention is not limited thereto, and various modifications and improvements made by those skilled in the art using the basic concept of the present invention as defined in the following claims also fall within the scope of the present invention.

What is claimed is:

1. A method for forming a seed layer, comprising:
an operation of forming an ion-passage hole by removing a portion of an insulating layer in a workpiece arranged such that a metal-pattern layer is disposed below and the insulating layer is disposed over it;
a masking operation of forming a metal mask layer on the insulating layer; and
a sputtering operation of forming a seed layer on the insulating layer by plasma sputtering;
wherein the metal mask layer is connected to the metal-pattern layer through a sidewall surface of the ion-passage hole.

2. The method for forming a seed layer according to claim 1,
wherein the ion-passage hole is provided so that at least a portion of the metal-pattern layer is exposed.

3. The method for forming a seed layer according to claim 1,
wherein the sidewall surface of the ion-passage hole allows charge transfer between the metal mask layer and the metal-pattern layer.

4. The method for forming a seed layer according to claim 1,
wherein a glass core is disposed under the metal-pattern layer,
the insulating layer is an upper insulating layer disposed over the glass core, and
the metal-pattern layer is a core electrically conductive layer or an upper electrically conductive layer.

5. The method for forming a seed layer according to claim 1,
wherein the ion-passage hole is formed by laser drilling the insulating layer.

6. The method for forming a seed layer according to claim 1,
wherein the sputtering operation comprises positioning the workpiece in a process chamber, evacuating the process chamber to vacuum conditions, generating plasma, and depositing a target material on a substrate.

7. The method for forming a seed layer according to claim 1,
wherein, through the ion-passage hole, occurrence of a potential difference between the metal mask layer and the metal-pattern layer is suppressed.

8. The method for forming a seed layer according to claim 1,
wherein occurrence of dielectric-breakdown phenomena during the sputtering operation is substantially suppressed.

9. A plasma etching method, comprising:
an operation of forming an ion-passage hole by removing a portion of an insulating layer in a workpiece arranged such that a metal-pattern layer is disposed below and the insulating layer is disposed over it;
a masking operation of disposing a metal mask layer on the insulating layer; and
a via-forming operation of providing a blind via in the insulating layer by plasma etching;
wherein the metal mask layer is connected to the metal-pattern layer through a sidewall surface of the ion-passage hole.

10. The plasma etching method according to claim 9,
wherein the ion-passage hole is provided so that at least a portion of the metal-pattern layer is exposed, and the sidewall surface of the ion-passage hole allows charge transfer between the metal mask layer and the metal-pattern layer.
